(19) United States
(12) Patent Application Publication
(10) Pub. No.: US 2018/0342345 A1
(43) Pub. Date: Nov. 29, 2018

(54) COIL MODULE FOR WIRELESS COMMUNICATIONS AND METHOD OF MANUFACTURING THE SAME

(71) Applicant: Samsung Electro-Mechanics Co., Ltd., Suwon-si (KR)

(72) Inventors: Jae Gen EOM, Suwon-si (KR); Hee Seung KIM, Suwon-si (KR); Young Min CHEON, Suwon-si (KR); Soon Joung YIO, Suwon-si (KR); Gie Hyoun KWEON, Suwon-si (KR); Jae Hyuk JANG, Suwon-si (KR); Jae Sun WON, Suwon-si (KR)

(73) Assignee: Samsung Electro-Mechanics Co., Ltd., Suwon-si (KR)

(21) Appl. No.: 15/949,699

(22) Filed: Apr. 10, 2018

(30) Foreign Application Priority Data
May 24, 2017 (KR) 10-2017-0064102
Jul. 21, 2017 (KR) 10-2017-0092836
Feb. 9, 2018 (KR) 10-2018-0016078

(51) Int. Cl. H01F 27/28; H05K 1/02; H05K 1/18; H04B 5/00

(52) U.S. Cl. CPC H01F 27/28; H05K 1/028; H01F 27/24; H04B 5/0081; H05K 1/181

(57) ABSTRACT

A coil module for wireless communications includes: a coil part formed by a molded substrate and having a solenoid shape; and a magnetic member disposed in an insertion hole of the coil part.

### CROSS-REFERENCE TO RELATED APPLICATIONS

This application claims benefit under 35 U.S.C. § 119(a) of Korean Patent Application No. 10-2017-0064102 filed on May 24, 2017, Korean Patent Application No. 10-2017-0092836 filed on Jul. 21, 2017, and Korean Patent Application No. 10-2018-0016078 filed on Feb. 9, 2018, in the Korean Intellectual Property Office, the entire disclosures of which are incorporated herein by reference for all purposes.

### BACKGROUND

### 1. Field

The following description relates to a coil module for wireless communications.

### 2. Description of Related Art

In accordance with growth in the portable phone market, an adoption rate of a wireless charging function has recently increased. The market size for wireless chargers is expected to become even larger, considering that various products, such as desks and tables, currently include the wireless charging function.

A receiving unit for implementing the wireless charging function has recently been provided with functions such as a near field communications (NFC) function, a magnetic secure transmission (MST) function, and a wireless power consortium (WPC) function, in combination with each other. A portable phone including the receiving unit may be required to have a thin structure due to a small thickness of the portable phone.

In addition, a pattern for the MST may be formed on opposite surfaces of a circuit board or may be formed on one surface of each of two circuit boards. In this example, the patterns for the MST formed on the opposite surfaces of the circuit board or formed on one surface of each of the two circuit boards are connected through a via.

Accordingly, due to the formation of the via, a manufacturing cost may be increased and a manufacturing yield may be decreased.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a coil module for wireless communications includes: a coil part formed by a molded substrate and having a solenoid shape; and a magnetic member disposed in an insertion hole of the coil part.

The substrate may include a flexible circuit board.

The substrate may be a single-sided substrate including a base layer and a metal layer formed on one surface of the base layer.

The metal layer and the base layer may be disposed above and below the magnetic member, and an order in which the metal layer and the base layer are disposed above the magnetic member may be the same as an order in which the metal layer and the base layer are disposed below the magnetic member.

The coil module for wireless communications of claim 3, wherein the metal layer includes a first pattern connected to a connection terminal, a second pattern connected to the first pattern and having the solenoid shape, and a third pattern connected to the second pattern and connected to another connection terminal.

The first pattern may have a bar shape extending in a length direction of the second pattern at an outer side of the second pattern. The third pattern may have the bar shape extending in a width direction of the second pattern at an outer end portion of the second pattern.

The second pattern may include first pattern members disposed on the magnetic member, second pattern members disposed below the magnetic member, and connection pattern members disposed at opposite sides of the magnetic member and connecting corresponding ones of the first pattern members and the second pattern members to each other.

Short preventing grooves for preventing a short circuit with an adjacent connection pattern member, among the connection pattern members, may be disposed at opposite sides of the connection pattern members.

Inclined parts may be disposed at opposite end portions of the first pattern members and the second pattern members to form the insertion hole.

The first pattern members may be disposed above the connection pattern members. The second pattern members may be disposed below the connection pattern members.

The magnetic member may include a magnetic sheet having a plate shape, and a cover sheet attached to opposite surfaces of the magnetic sheet.

The magnetic member may include a cross section of a concave-convex shape.

The magnetic member may include mounting grooves formed in opposite surfaces of the magnetic member. A pattern included in the coil part may be inserted into the mounting grooves.

The coil module for wireless communications may further include an exterior cover sheet attached to an outer surface of the coil part and enclosing the coil part.

In another general aspect, a coil module for wireless communications includes: a coil part having a solenoid shape and formed by a molded metal plate; and a magnetic member inserted into an insertion hole of the coil part. The coil module for wireless communications may include a magnetic sheet having a plate shape, and a cover sheet attached to opposite surfaces of the magnetic sheet.

The magnetic member may further include a cross section having a concave-convex shape.

The magnetic member may further include mounting grooves formed in opposite surfaces of the magnetic sheet, wherein a pattern included in the coil part is inserted into the mounting grooves.

In another general aspect, a method to manufacture a coil module for wireless communications includes: etching a metal layer on a flexible circuit board including the metal layer and a base layer; shaping the flexible circuit board to have a solenoid shape disposed around an insertion hole; and inserting a magnetic member in the insertion hole.

The shaping of the flexible circuit board to have the solenoid shape may include molding the flexible circuit board to include a first pattern configured to be connected to a connection terminal, a second pattern connected to the first pattern and having the solenoid shape, and a third pattern connected to the second pattern and configured to be connected to another connection terminal.

The shaping of the flexible circuit board may further include pressurizing the second pattern to form the insertion hole.

The shaping of the flexible circuit board may further include molding the flexible circuit board by a press-blanking process.

Other features and aspects will be apparent from the following detailed description, the drawings, and the claims.

### BRIEF DESCRIPTION OF DRAWINGS

FIG. 1 is a schematic cross-sectional view illustrating a coil module for wireless communications, according to an embodiment.

FIG. 2 is an exploded perspective view illustrating a coil part and a magnetic member of the coil module, according to an embodiment.

FIG. 3 is a plan view illustrating the coil part, according to an embodiment.

FIG. 4 is an enlarged view illustrating a part A of FIG. 2.

FIG. 5 is an enlarged view illustrating a part B of FIG. 2.

FIG. 6 is a schematic cross-sectional view illustrating a coil module for wireless communications, according to another embodiment.

FIG. 7 is an exploded perspective view illustrating a coil part and a magnetic member of the coil module, according to another embodiment.

FIG. 8 is an enlarged view illustrating a part C of FIG. 7.

FIG. 9 is an enlarged view of a part D of FIG. 7.

FIG. 10 is a cross-sectional view illustrating a coil part, according to another embodiment

FIG. 11 is a cross-sectional view illustrating a coil part, according to another embodiment.

FIG. 12 is a cross-sectional view illustrating a coil part, according to another embodiment.

FIG. 13 is a cross-sectional view illustrating a coil part included, according to another embodiment.

FIG. 14 is an exploded perspective view illustrating a coil part and a magnetic member of a coil module for wireless communications, according to another embodiment.

FIG. 15 is a perspective view illustrating the coil part of FIG. 14.

FIG. 16 is a partially cut-way perspective view illustrating the coil part and the magnetic member of FIG. 14.

FIG. 17 is an exploded perspective view illustrating a coil part and a magnetic member of a coil module for wireless communications, according to another embodiment.

FIG. 18 is a rear view illustrating a portable terminal including a coil module for wireless communications, according to another embodiment.

FIG. 19 is a cross-sectional view taken along a line I-I′ of FIG. 18.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

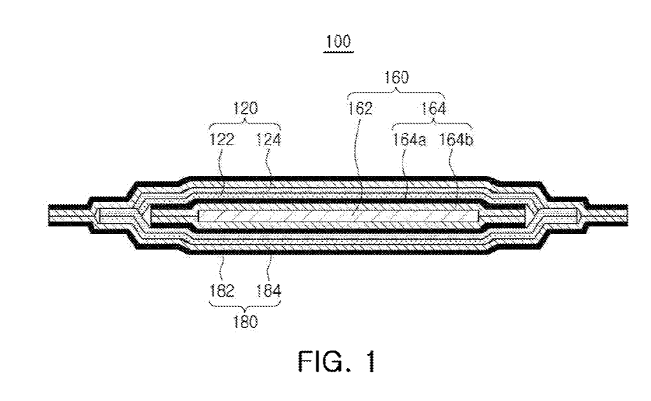

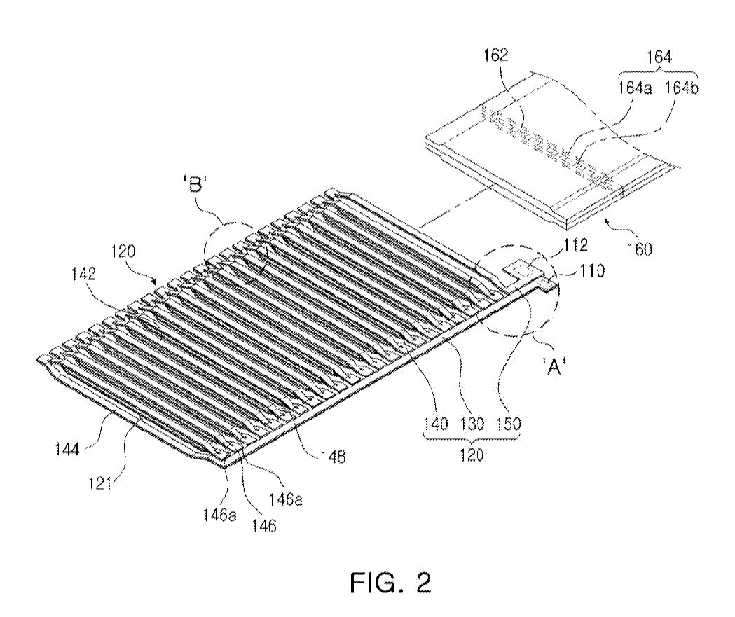

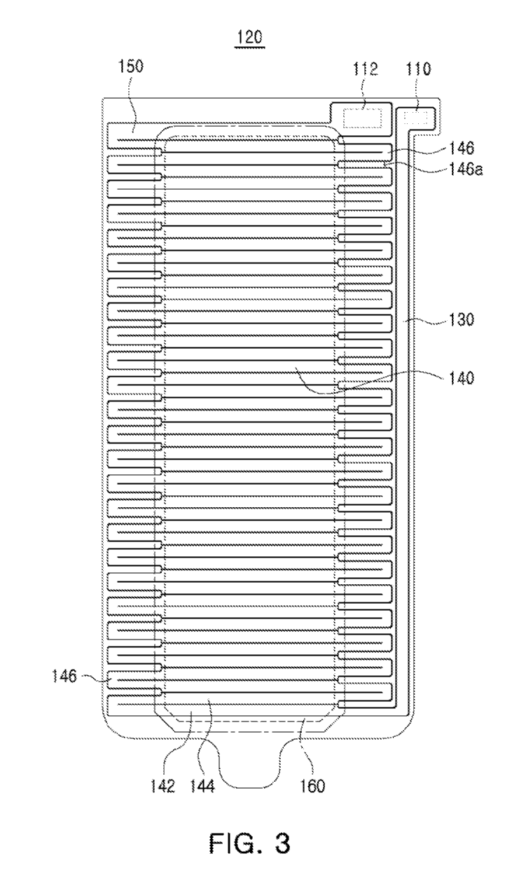

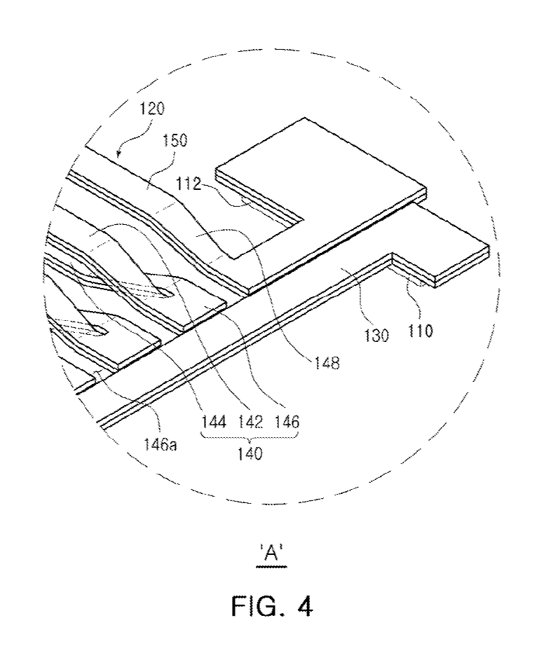

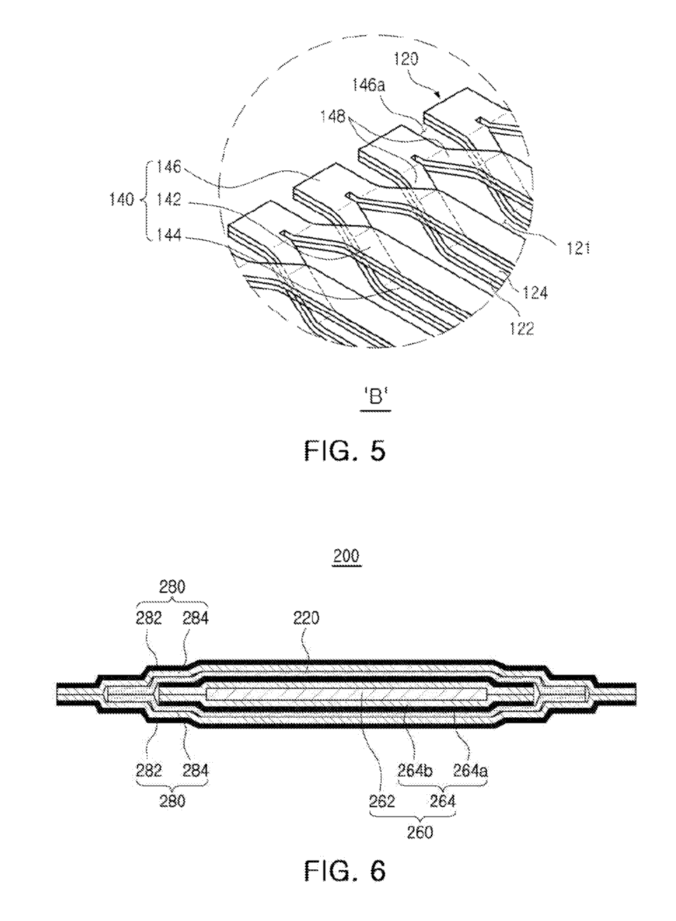

FIG. 1 is a schematic cross-sectional view illustrating a coil module 100 for wireless communications, according to an embodiment. FIG. 2 is an exploded perspective view illustrating a coil part 120 and a magnetic member 160 of the coil module 100, according to an embodiment. FIG. 3 is a plan view illustrating the coil part 120. FIG. 4 is an enlarged view illustrating a part A of FIG. 2, and FIG. 5 is an enlarged view illustrating a part B of FIG. 2.

Referring to FIGS. 1 through 5, the coil module 100 includes, for example, the coil part 120, the magnetic member 160, and an exterior cover sheet 180.

The coil part 120 may have a solenoid shape, and be molded from a substrate. In detail, referring to FIGS. 2 and 5, the coil part 120 may have the solenoid shape in which an insertion hole 121 is formed in a central portion of the coil part 120. That is, the coil part 120 may be a generally spiral coil-shaped body, with the insertion hole 121 formed at a central portion of the spiral coil-shaped body. As an example, the coil part 120 is molded from a single-sided flexible circuit board. As shown in FIGS. 2 and 5, the coil part 120 includes a base layer 122 and a metal layer 124 formed on one surface of the base layer 122.

In an example, the base layer 122 is formed of, a polyimide material and the metal layer 124 is formed of a copper material. Further, as shown in FIGS. 2 through 5, the metal layer 124 includes a first pattern 130 connected to a connection terminal 110, a second pattern 140 connected to the first pattern 130 and having a solenoid shape (e.g., a generally spiral coil shape), and a third pattern 150 connected to the second pattern 140 and connected to another connection terminal 112.

Referring to FIGS. 2 and 3, the first pattern 130 is disposed at one side of the second pattern 140, is connected to one end portion of the second pattern 140, and extends parallel to the second pattern 140. The third pattern 150 is connected to another end portion of the second pattern 140. For example, the third pattern 150 forms an end pattern portion of the second pattern 140.

In other words, the first pattern 130 is disposed outside the second pattern 140, at one side of the second pattern 140, and has a substantially bar shape in a length direction of the second pattern 140. Further, the third pattern 150 is disposed outside the second pattern 140, and forms an end pattern portion of the second pattern 140 having a bar shape in a width direction of the second pattern 140.

Further, the first, second, and third patterns 130, 140, and 150 may be disposed to be spaced apart from each other by a predetermined or specified distance to prevent a short-circuit.

In addition, as shown in FIGS. 2, 3, and 5, the second pattern 140 includes first, upper pattern members 142 disposed above the magnetic member 160, second, lower pattern members 144 disposed below the magnetic member 160, and connection pattern members 146 disposed at opposite sides of the magnetic member 160 and connecting corresponding first pattern members 142 and second pattern members 144 to each other at end portions of the corresponding first pattern members 142 and second pattern members 144. The first pattern members 142, the second pattern members 144, and the connection pattern members 146 form an upper patter portion, a lower pattern portion, and a connection pattern portion, respectively, of the second pattern 140. As an example, the first pattern members 142 and the second pattern members 144 extend in a width direction of the second pattern 140. As an example, the connection pattern members 146 may have a bar shape.

Further, as shown in FIGS. 2, 4, and 5, inclined parts 148 are provided at opposite end portions of the first pattern members 142 and the second pattern members 144 in order to form the insertion hole 121 for inserting the magnetic member 160 such that the magnetic member 160 is disposed within the coil part 120.

Accordingly, a spaced distance between central portions of the first pattern members 142 and the second pattern members 144 may be greater than a spaced distance between the opposite end portions of the first pattern members 142 and the second pattern members 144. In other words, a thickness of a central portion of the second pattern 140, in the width direction of the second pattern 140, may be greater than a thickness of an edge portion of the second pattern 140, in the width direction of the second pattern 140.

Referring to FIGS. 2 through 5, short prevention grooves 146a are disposed between adjacent connection pattern members 146 at opposite sides of the second pattern 140 to prevent a short circuit with an adjacent connection pattern member 146. Accordingly, a connection pattern member 146 may have a width, in the length direction of the second pattern 140 less than that of the first pattern member 142 and the second pattern member 144.

In addition, the first, second, and third patterns 130, 140, and 150 may be formed by etching.

Further, as illustrated in FIG. 1, the base layer 122 may have a shape corresponding to the shape of the first, second, and third patterns 130, 140, and 150 and may be molded to have the shape corresponding to the shape of the first, second, and third patterns 130, 140, and 150 by a press-blanking process.

Hereinafter, a method for forming the coil part 120 will be briefly described.

In the method for forming the coil part 120, the first, second, and third patterns 130, 140, and 150 are formed by etching the metal layer 124 of the single-sided flexible circuit board.

Thereafter, the base layer 122 is molded to have the shape corresponding to the first, second, and third patterns 130, 140, and 150 by the press-blanking process.

Thereafter, in a state in which the coil part 120 is mounted in a fixed jig (not shown), the second pattern 140 is formed to have a solenoid shape. The second pattern 140 may be formed in the solenoid shape by pressurizing either the first pattern members 142 or the second pattern members 144 of the second pattern 140 to form the insertion hole 121.

Referring to FIGS. 1 and 2, the magnetic member 160 is inserted into the insertion hole 121 of the coil part 120. As an example, the magnetic member 160 includes a magnetic sheet 162 having a plate shape and a cover sheet 164 attached onto opposite surfaces of the magnetic sheet 162. The cover sheet 164 may enclose the magnetic sheet 162. As an example, the cover sheet 164 includes a protective layer 164a and an adhesive layer 164b formed on a bottom surface of the protective layer 164a.

The protective layer 164a may be formed of a polyimide material, and prevents the magnetic sheet 162 from being damaged. In addition, the magnetic member 160 may have a shape corresponding to the shape of the insertion hole 121 of the coil part 120.

The magnetic sheet 162 may be sealed in the cover sheet 164. Accordingly, fine particles such as powder and the like that are separated or detached from the magnetic sheet 162 may be prevented from being exposed to the outside environment.

In addition, after the cover sheet 164 is attached onto the opposite sides of the magnetic sheet 162, the magnetic sheet 162 and the cover sheet 164 may be compressed. Therefore, the magnetic sheet 162 may be sealed by the cover sheet 164 to prevent the magnetic sheet 162 and the cover sheet 164 from being separated from each other.

Referring to FIG. 1, the exterior cover sheet 180 is attached onto an outer surface of the coil part 120 to enclose the coil part 120. As an example, the exterior cover sheet 180 also includes a protective layer 182 and an adhesive layer 184. As an example, the exterior cover sheet 180 is also bonded to top and bottom surfaces of the coil part 120.

After the exterior cover sheet 180 is bonded to the top and bottom surfaces of the coil part 120, end portions of the first coil 130 and the third coil 150 of the coil part 120 are externally exposed from the exterior cover sheet 180 for an electrical connection with an outside component by the connection terminals 110 and 112.

As an example, the coil module 100 is a coil module for near field communications (NFC) and/or magnetic secure transmission (MST).

A stacking order of the coil module 100 will be briefly described below, with reference to FIG. 1.

As illustrated in FIG. 1, the exterior cover sheet 180 is disposed at the outermost portion of the coil module 100, the coil part 120 is disposed inside the exterior cover sheet 180, and the magnetic member 160 is disposed in the coil part 120.

In more detail, in a bottom portion of the coil module 100, the exterior cover sheet 180 is disposed at the lowermost portion of the coil module 100. The exterior cover sheet 180 may be disposed so that the protective layer 182 is exposed to the outside environment. Therefore, the protective layer 182 is disposed below the adhesive layer 184, and the adhesive layer 184 is disposed above the protective layer 184.

In addition, the coil part 120 is disposed on the adhesive layer 184 in the bottom portion of the coil module 100. Since the coil part 120 is molded to have the solenoid shape from one single-sided flexible circuit board, the base layer 122 and the metal layer 124 of the coil part 120 are disposed in the order below.

Also, in the bottom portion of the coil module, the base layer 122 is disposed on the adhesive layer 184 and the metal layer 124 is disposed on the base layer 122. In addition, the metal layer 124 disposed on the adhesive layer 184 is a component forming the second pattern members 144.

In addition, as illustrated in FIG. 1, the magnetic member 160 is disposed on the second pattern members 144 in the bottom portion of the coil module 100. The cover sheet 164 is disposed at the outer portion of the magnetic member 160 and the magnetic sheet 162 is disposed in the cover sheet 164.

Therefore, in the bottom portion of the coil module 100, the cover sheet 164 is disposed on the metal layer 124 forming the second pattern members 144. The protective layer 164a of the cover sheet 164 is disposed on the metal layer 124 and the adhesive layer 164b is disposed on the protective layer 164a.

In addition, the magnetic sheet 162 is disposed on the cover sheet 164 in a top portion of the coil module 100.

In addition, the cover sheet 164 is disposed on the magnetic sheet 162 in the top portion of the coil module 100, where the cover sheet 164 is disposed on the magnetic sheet 162 so as to be disposed in the order of the adhesive layer 164b and the protective layer 164a on the adhesive layer 164a.

In addition, the coil part 120 is disposed on the cover sheet 164 in the top portion of the coil module 100. In addition, the base layer 122 and the metal layer 124 of the coil part 120 are disposed in the order below in the top portion of the coil module 100.

The base layer 122 is disposed on the protective layer 164a of the cover sheet 164 and the metal layer 124 is disposed on the base layer 122. In addition, the metal layer 124 disposed on the protective layer 164a is a component forming the first pattern members 142.

In addition, the exterior cover sheet 180 is disposed on the uppermost portion of the coil module 100. The exterior cover sheet 180 is disposed on the coil part 120 in the top portion of the coil module 100 so as to be disposed in the order of the adhesive layer 184 and the protective layer 182 on the adhesive layer 184.

As such, since the coil part 120 is molded to have the solenoid shape from the one single-sided flexible circuit board, the base layer 122 and the metal layer 124 of the coil part 120 are sequentially disposed in the order of the metal layer 124, the base layer 122, the metal layer 124, and the base layer 122 from the top to the bottom in a cross section of the coil part 120.

As described above, since the coil part 120 is molded from the single-sided flexible circuit board, a manufacturing yield may be improved and a manufacturing cost may be reduced in comparison with conventional coil parts.

In other words, since the coil part 120 is molded by performing an etching and press-blanking process for the single-sided flexible circuit board, a process of forming a via may be omitted, thereby improving the manufacturing yield and reducing the manufacturing cost in comparison with conventional coil parts.

Although the foregoing example describes an example in which the coil part 120 is molded from a single-sided flexible circuit board, the coil part 120 is not limited thereto and may also be molded from a doubled-sided flexible circuit board. For example, the second pattern members 142 and the second pattern members 144 may be disposed on opposite surfaces of the coil part 120, respectively. In this case, the first pattern members 142 and the second pattern members 144 may be alternately disposed on the opposite surfaces of the coil part 120.

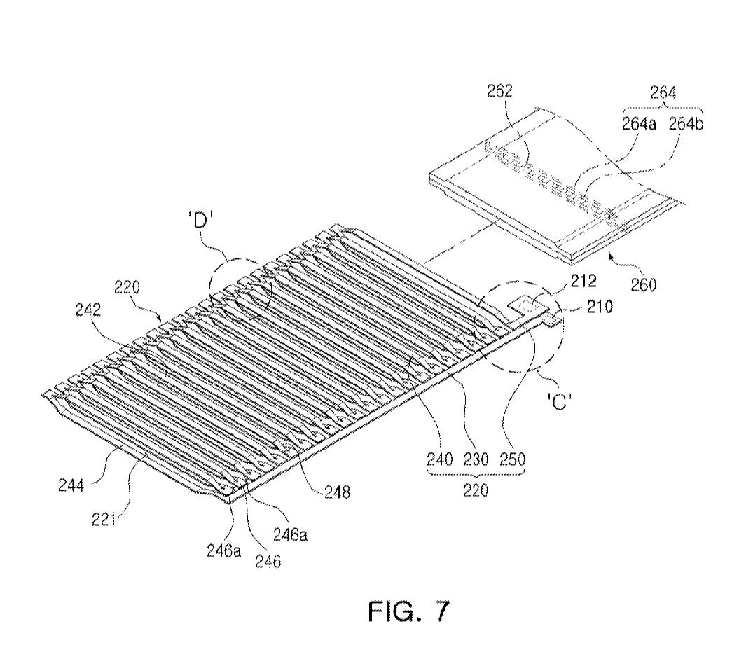

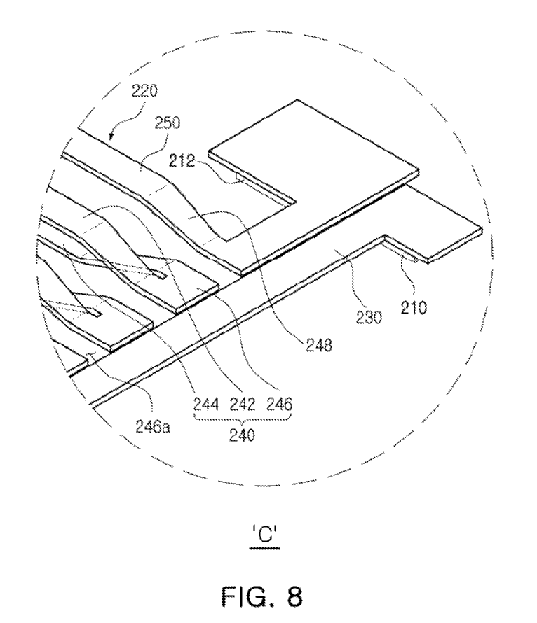

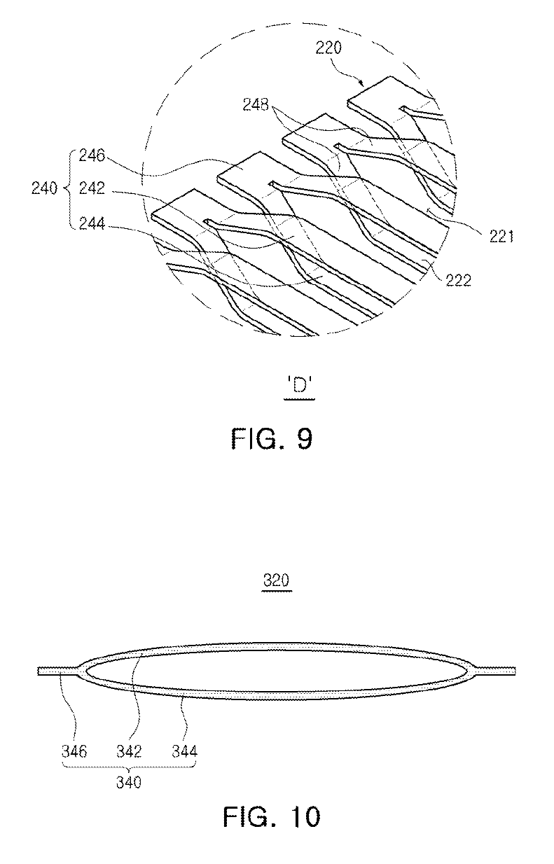

FIG. 6 is a schematic cross-sectional view illustrating a coil module 200 for wireless communications, according to another embodiment. FIG. 7 is an exploded perspective view illustrating a coil part 220 and a magnetic member 260 of the coil module 200, according to another embodiment. FIG. 8 is an enlarged view illustrating a part C of FIG. 7, and FIG. 9 is an enlarged view of a part D of FIG. 7.

Referring to FIGS. 6 through 9, the coil module 200 includes, for example, the coil part 220, the magnetic member 260, and an exterior cover sheet 280.

The coil part 220 may be molded by a press-blanking process of a metal plate. As an example, the coil part 220 is formed by performing the press-blanking process for a copper plate. In addition, as shown in FIGS. 7 and 9, an insertion hole 221 into which the magnetic member 260 is inserted is formed in the coil part 220. In other words, the coil part 220 may have a solenoid shape.

Referring to FIGS. 7 and 8, coil part 220 includes a first pattern 230 connected to a connection terminal 210, a second pattern 240 connected to the first pattern 230 and having a solenoid shape, and a third pattern 250 connected to the second pattern 240 and connected another connection terminal 212. The first pattern 230, the second pattern 240, and the third pattern 250 may have a configuration similar to that of the first pattern 130, the second pattern 140, and the third pattern 150 in the embodiment of FIGS. 1-5.

Referring to FIGS. 7-9, the second pattern 240 includes first, upper pattern members 242 disposed on the magnetic member 260, second, lower pattern members 244 disposed below the magnetic member 260, and connection pattern members 246 disposed at opposite sides of the magnetic member 260 and connecting corresponding first pattern members 242 and second pattern members 244 to each other at end portions of the corresponding first pattern members 242 and second pattern members 244. The first pattern members 242, the second pattern members 244, and the connection pattern members 246 form an upper patter portion, a lower pattern portion, and a connection pattern portion, respectively, of the second pattern 240.

Further, inclined parts 248 are provided at opposite end portions of the first pattern members 242 and the second pattern members 244 in order to form the insertion hole 221 for inserting the magnetic member 260 such that the magnetic member 260 is disposed within the coil part 220.

As an example, the first pattern members 242 and the second pattern members 244 are disposed in alternating order. Further, as an example, the connection pattern members 246 have a bar shape. Short prevention grooves 246a are disposed at opposite sides of the connection pattern members 246 to prevent a short circuit with an adjacent connection pattern 246.

A method for manufacturing the coil part 220 will be briefly described with reference to FIGS. 6-9. After the first, second, and third patterns 230, 240, and 250 are formed by performing a press-blanking process for a metal plate, either the first pattern members 242 or the second pattern members 244 protrude upwardly in a state in which the coil part 220 is mounted in a fixing jig (not shown). Thereafter, the other of the first pattern members 242 and the second pattern members 244 protrude downwardly.

However, the first pattern members 242 and the second pattern members 244 are not limited to the foregoing example, and the insertion hole 221 may also be formed by pressurizing only the first pattern members 242 or the second pattern members 244 so as to protrude upwardly or downwardly.

As such, since the coil part 220 is formed to have the solenoid shape, a via for connecting the first pattern members 242 and the second pattern members 244 disposed on and below the magnetic sheet 260 need not be formed. Accordingly, a manufacturing yield may be improved.

In addition, since the coil part 220 is molded by the press-blanking process, the manufacturing yield may be improved.

The magnetic member 260 is inserted into the insertion hole 221 of the coil part 220. As an example, referring to FIGS. 6 and 7, the magnetic member 260 includes a magnetic sheet 262 having a plate shape and a cover sheet 264 attached onto opposite surfaces of the magnetic sheet 262. In detail, the cover sheet 264 may enclose the magnetic sheet 262. As an example, the cover sheet 264 includes a protective layer 264a and an adhesive layer 264b formed on a bottom surface of the protective layer 264a.

The protective layer 264a may be formed of a polyimide material, and prevents the magnetic sheet 262 from being damaged. In addition, the magnetic member 260 may have a shape corresponding to the shape of the insertion hole 221 of the coil part 220.

As shown in FIG. 6, the exterior cover sheet 280 is attached onto an outer surface of the coil part 220 to enclose the coil part 220. As an example, the exterior cover sheet 280 also includes a protective layer 282 and an adhesive layer 284. As an example, the exterior cover sheet 280 is also bonded to top and bottom surfaces of the coil part 220.

As described above, since the coil part 220 may be manufactured by the press-blanking process of the metal plate, a manufacturing cost may be reduced and the manufacturing yield may be improved in comparison with conventional coil parts.

Hereinafter, additional example coil parts will be described with reference to the accompanying drawings.

FIG. 10 is a cross-sectional view illustrating a coil part 320, according to another embodiment.

Referring to FIG. 10, the coil part 320 includes a second pattern 340 having a cross section of a substantially oval shape. The second pattern 340 includes first, upper pattern members 342, second, lower pattern members 344, and connection pattern members 346. The first pattern members 342 are upwardly convex and the second pattern members 344 are downwardly convex. In addition, the connection pattern members 346 are disposed at opposite sides of corresponding first pattern members 342 and the second pattern members 344 to connect corresponding first pattern members 342 and second pattern members 344 to each other. The coil part 320 may be formed of a metal plate or a single-sided flexible circuit board.

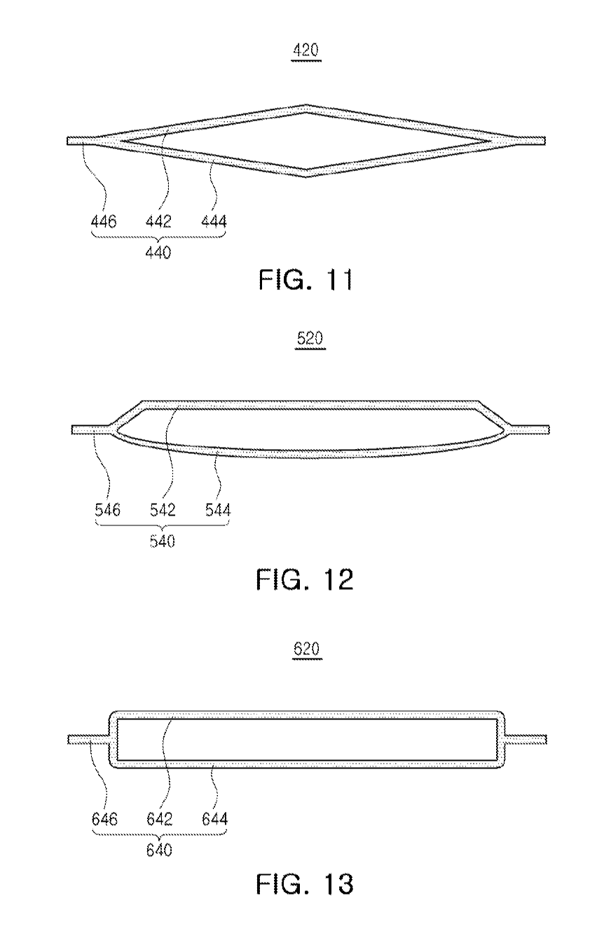

FIG. 11 is a cross-sectional view illustrating a coil part 420, according to another embodiment.

Referring to FIG. 11, the coil part 420 includes a second pattern 440 having a cross section of a substantially diamond shape. The second pattern 440 includes first, upper pattern members 442, second, lower pattern members 444, and connection pattern members 446. The first pattern members 442 are upwardly convex and the second pattern members 444 are downwardly convex. In addition, the connection pattern members 446 are disposed at opposite sides of the first pattern members 442 and the second pattern members 444 to connect corresponding first pattern members 442 and second pattern members 444 to each other.

The coil part 420 may be formed of a metal plate or a single-sided flexible circuit board.

FIG. 12 is a cross-sectional view illustrating a coil part 520, according to another embodiment.

Referring to FIG. 12, the coil part 520 includes a second pattern 540, and the second pattern 540 includes first, upper pattern members 542, second pattern members 544, and connection pattern members 546. The first pattern members 542 are upwardly convex and have a cross section of a quadrangular shape, and the second pattern members 544 are downwardly convex and have a cross section of an oval shape. In addition, the connection pattern members 546 are disposed at opposite sides of the first pattern members 542 and the second pattern members 544 to connect the corresponding first pattern members 542 and the second pattern members 544 to each other.

FIG. 13 is a cross-sectional view illustrating a coil part 620, according to another embodiment.

Referring to FIG. 13, the coil part 620 includes a second pattern 640 having a cross section of a substantially quadrangular shape. The second pattern 640 includes first, upper pattern members 642, second, lower pattern members 644, and connection pattern members 646. The first pattern members 642 are upwardly convex and the second pattern members 644 are downwardly convex. In addition, the connection pattern members 646 are disposed at opposite sides of the first pattern members 642 and the second pattern members 644 to connect corresponding first pattern members 642 and second pattern members 644 to each other.

The coil part 620 may be formed of a metal plate or a single-sided flexible circuit board.

In the above description, example coil parts 320, 420, 520, and 620 have been simply described with respect different shapes of the coil parts, but a shape of a coil part is not limited thereto, and may be modified in various ways.

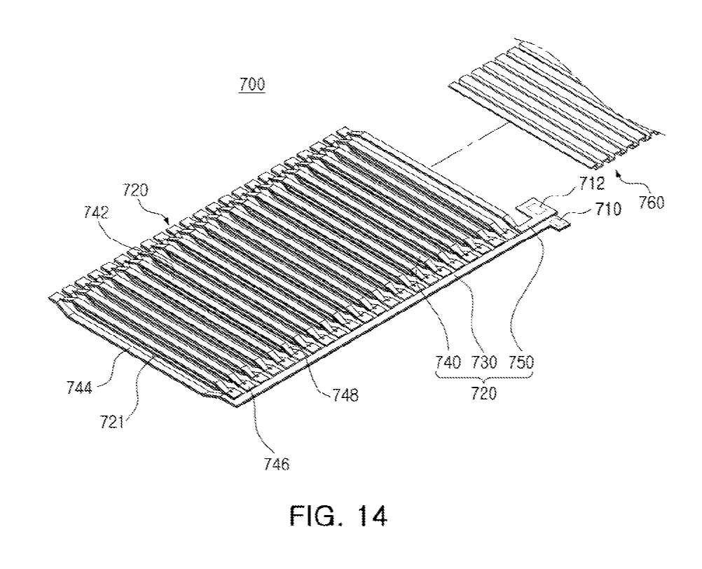

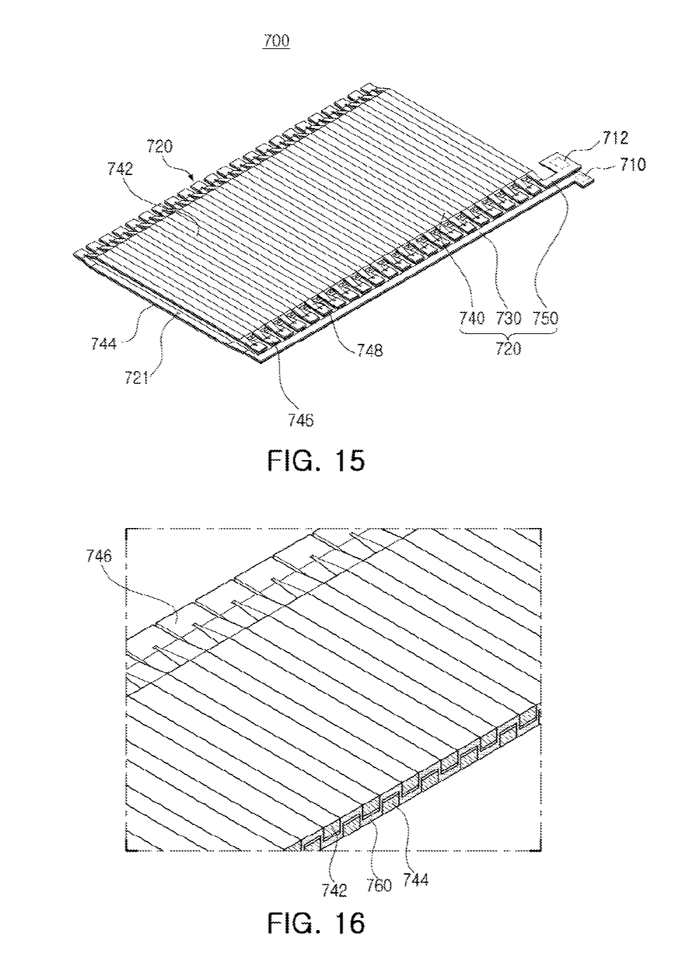

FIG. 14 is an exploded perspective view illustrating a coil part 720 and a magnetic member 760 of a coil module 700 for wireless communications, according to another embodiment. FIG. 15 is a perspective view illustrating the coil part 720. FIG. 16 is a partially cut-way perspective view illustrating the coil part 720 and the magnetic member 760.

Referring to FIGS. 14 through 16, the coil module 700 includes, for example, the coil part 720, the magnetic member 760, and an exterior cover sheet (not shown), such as the exterior cover sheet 180 (FIG. 1) or the exterior cover sheet 280 (FIG. 6).

The coil part 720 may be molded by a press-blanking process on a metal plate. As an example, the coil part 720 is formed by performing the press-blanking process on a copper plate. In addition, an insertion hole 721 into which the magnetic member 760 is inserted is formed in the coil part 720. In other words, the coil part 720 may have a solenoid shape.

Referring to FIGS. 14 and 15, the coil part 720 includes a first pattern 730 connected to any a connection terminal 710, a second pattern 740 connected to the first pattern 730 and having a solenoid shape, and a third pattern 750 connected to the second pattern 740 and connected to another connection terminal 712.

As shown in FIGS. 14 through 16, the second pattern 740 includes first, upper pattern members 742 disposed on the magnetic member 760, second pattern members 744 disposed below the magnetic member 760, and connection pattern members 746 disposed at opposite sides of the magnetic member 760 and connecting corresponding first pattern members 742 and second pattern members 744 to each other. The first pattern members 742, the second pattern members 744, and the connection pattern members 746 form an upper patter portion, a lower pattern portion, and a connection pattern portion, respectively, of the second pattern 740.

Further, as shown in FIGS. 14 and 15, inclined parts 748 are provided on opposite end portions of the first pattern members 742 and the second pattern members 744 in order to form the insertion hole 721 for receiving the magnetic member 760 in the insertion hole 721.

As an example, the first pattern members 742 and the second pattern members 744 are disposed in an alternating order. Further, as an example, the connection pattern members 746 have a bar shape.

A method for manufacturing the coil part 720 will be briefly described with respect to FIGS. 14 through 16. After the first, second, and third patterns 730, 740, and 750 are formed by performing a press-blanking process for a metal plate, either the first pattern members 742 or the second pattern members 744 protrude upwardly in a state in which the coil part 720 is mounted in a fixing jig (not shown). Thereafter, the other of the first pattern members 742 or the second pattern 744 protrude downwardly.

However, the first pattern members 742 or and the second pattern members 744 are not limited to the foregoing example, and the insertion hole 721 may also be formed by pressurizing only the first pattern members 742 or the second pattern members 744 so as to protrude upwardly or downwardly.

As such, since the coil part 720 is formed to have the solenoid shape, a via for connecting the first pattern members 742 and the second pattern members 744 disposed on and below the magnetic sheet 760 to each other need not be formed. Accordingly, a manufacturing yield may be improved.

In addition, since the coil part 720 is molded by the press-blanking process, the manufacturing yield may be improved.

The coil part 720 may be compressed after the magnetic member 760 is installed. For example, the coil part 720 may be compressed to reduce a size of the insertion hole 721 formed by the first pattern members 742 and the second pattern members 744 of the coil part 720. A detailed description of a process in which the coil part 720 is compressed will be provided below.

Referring to FIGS. 14 and 16, the magnetic member 760 is disposed in the insertion hole 721 of the coil part 720. The magnetic member 760 may have a concave-convex cross-sectional shape. In other words, the cross-sectional shape of the magnetic member 760 has alternating concave and convex portions. As an example, the magnetic member 760 includes mounting grooves 761 into which the first pattern members 742 and the second pattern members 744 of the coil part 720 are inserted. In other words, the first pattern members 742 and the second pattern members 744 are inserted into the mounting grooves 761 which are alternately disposed on opposite surfaces of the magnetic member 760 having the concave-convex cross-sectional shape. In more detail, the first pattern members 742 are disposed in the mounting grooves 761 disposed on one surface of the magnetic member 760 and the second pattern members 744 are disposed in the mounting grooves 761 disposed on the other surface of the magnetic member 760.

After the magnetic member 760 is inserted into the insertion hole 721 of the coil part 720, the coil part 720 is compressed. In this case, the first pattern members 742 and the second pattern members 744 of the coil part 720 are inserted into the mounting grooves 761 of the magnetic member 760.

Since a thickness of the coil part 720 is reduced by the compression after the coil part 720 and the magnetic member 760 are assembled, thinness may be achieved. In detail, the first pattern members 742 and the second pattern members 744 of the coil part 720 are inserted into the mounting grooves 761 of the magnetic member 760 by the compression after the coil part 720 and the magnetic member 760 are assembled, such that thinness of the coil module 700 is achieved.

As described above, since the magnetic member 760 has the cross section of the concave-convex shape, an overall thickness of the coil module 700 may be reduced. Further, since the coil part 720 may be manufactured by performing the press-blanking process for the metal plate, manufacturing costs may be reduced and a manufacturing yield may be improved.

Although the example embodiment disclosed above describes an example in which the coil part 720 is molded from the metal plate, the coil part 720 is not limited to such an example, and may also be molded from the single-sided flexible circuit board like the coil part 120 of the coil module 100 according to the embodiment of FIGS. 1 through 5. Further, the coil part 720 may also be molded from a double-sided flexible circuit board. For example, the first pattern members 742 and the second pattern members 744 may be disposed on the opposite surfaces of the coil part 720, respectively. In this case, the first pattern members 742 and the second pattern members 744 may be alternately disposed on the opposite surfaces of the coil part 720.

In addition, the coil part 720 may be formed of a wire rod, and the mounting grooves 761, having a spiral shape, may be formed in the magnetic member 760. In detail, the coil part 720 may be wound around the magnetic member 760 so that the coil part 720 formed of the wire rod is disposed in the mounting grooves 761 having the spiral shape.

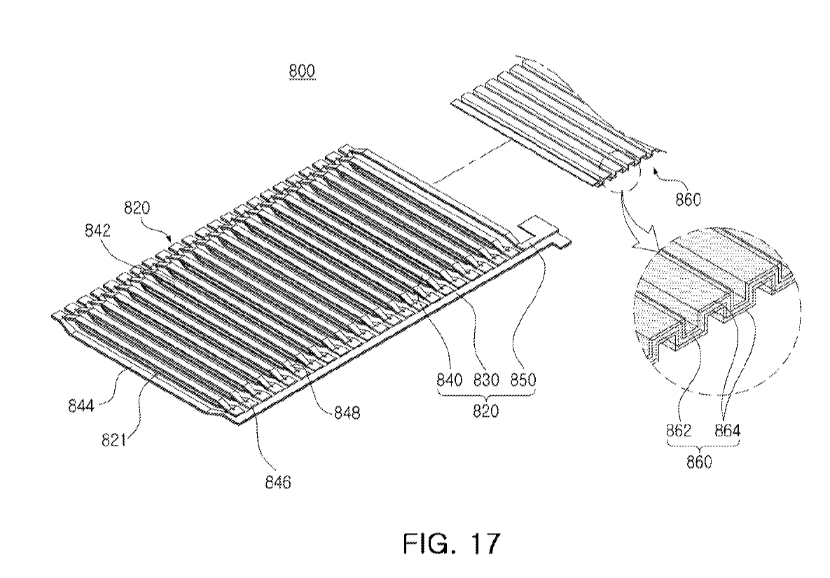

FIG. 17 is an exploded perspective view illustrating a coil part 820 and a magnetic member 860 of a coil module 800 for wireless communications, according to another embodiment.

Referring to FIG. 17, the coil module 800 includes, for example, the coil part 820, the magnetic member 860, and an exterior cover sheet (not shown), such as the exterior cover sheet 180 (FIG. 1) or the exterior cover sheet 280 (FIG. 6).

The coil part 820 is the same component as that of the coil part 720 described above, and a detailed description thereof will be omitted herein and will be replaced with the above-mentioned description.

The magnetic member 860 is disposed in an insertion hole 821 of the coil part 820. The magnetic member 860 has a cross section having a concave-convex shape. As an example, the magnetic member 860 includes mounting grooves 861 into which first, upper pattern members 842 and second, lower pattern members 844 of the coil part 820 are inserted. In other words, the first pattern members 842 and the second pattern members 844 are inserted into the mounting grooves 861 which are alternately disposed on opposite surfaces of the magnetic member 860. In more detail, the first pattern members 842 are disposed in the mounting grooves 861 disposed on one surface of the magnetic member 860 and the second pattern 844 may be disposed in the mounting grooves 861 disposed on the other surface of the magnetic member 860.

After the magnetic member 860 is inserted into the insertion hole 821 of the coil part 820, the coil part 820 is compressed. In this case, the first pattern members 842 and the second pattern members 844 are inserted into the mounting grooves 861 of the magnetic member 860.

As such, since a thickness of the coil part 820 is reduced by the compression after the coil part 820 and the magnetic member 860 are assembled, thinness may be achieved. For example, the first pattern members 842 and the second pattern members 844 of the coil part 820 are inserted into the mounting grooves 861 of the magnetic member 860 by the compression after the coil part 820 and the magnetic member 860 are assembled, such that thinness of the coil module 800 may be achieved.

In addition, the magnetic member 860 includes a magnetic sheet 862 having a cross section of a concave-convex shape, and cover sheets 864 attached onto opposite surfaces of the magnetic sheet 862. The cover sheets 864 may enclose the magnetic sheet 862.

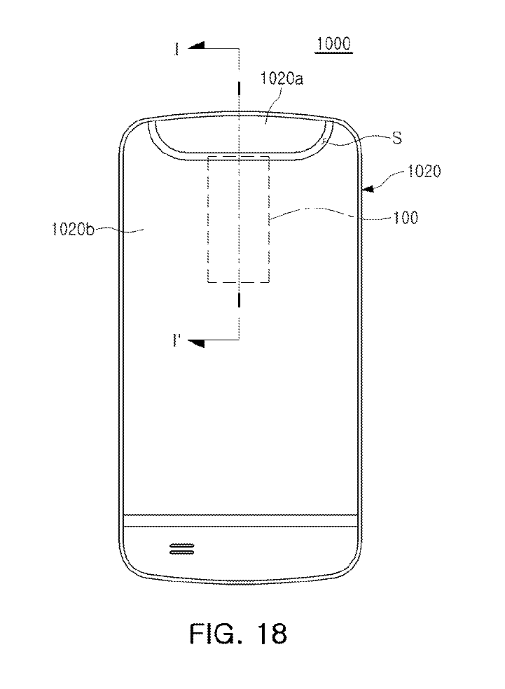

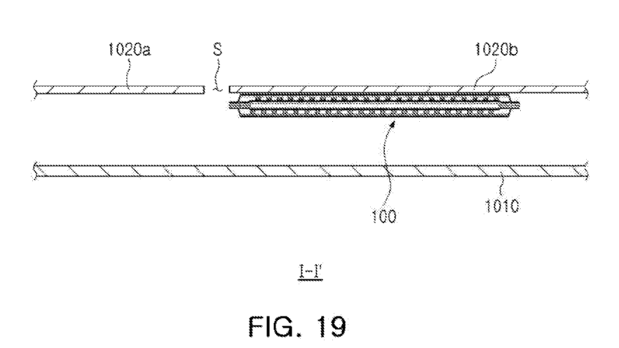

FIG. 18 is a rear view illustrating a portable terminal 1000 including the coil module 100, according to an embodiment. FIG. 19 is a cross-sectional view taken along a line I-I′ of FIG. 18.

Referring to FIGS. 18 and 19, the portable terminal 1000 includes the coil module 100 disposed between a terminal body 1010 and a cover 1020.

The cover 1020, which is a rear cover coupled to the terminal body 1010 to complete the portable terminal 1000, may be a battery cover separated from the terminal body 1010 when a battery is replaced. However, the cover 1020 is not limited to such an example, and may also include an integral cover which is difficult to separate from the terminal body 1010.

The cover 1020 according to the present exemplary embodiment may be formed of a metal material (e.g., aluminum or the like) and may include at least two plates 1020a and 1020b coupled to each other to complete a flat plate shape.

In an example in which the entirety of the cover 1020 is formed of the metal material, since a radio wave radiated from the coil module 100 is shielded by the cover 1020, wireless communications may not be properly performed.

To solve this problem, the cover 1020 includes plates 1020a and 1020b. The disclosed embodiment describes an example in which the cover 1020 includes two plates 1020a and 1020b. However, the cover 1020 is not limited to this example, and may be modified in various ways. For example, the cover 1020 may include three or more division plates, as needed.

The plates 1020a and 1020b may be formed of a metal material, and a slit S is formed between the plates 1020a and 1020b. The slit S may be formed by cutting the cover 1020. The slit S may be formed as an empty space and may be filled with a non-conductive material such as resin or a polymer as needed.

The coil module 100 is disposed in the portable terminal 1000. In detail, the coil module 100 is disposed on an inner surface of the cover 1020 and disposed so that at least a portion of the coil module 100 overlaps with the slit S. For example, in the case in which the slit S is formed as the empty space, the coil module 100 is exposed to the outside through the slit S so that at least a portion of the coil module 100 is identifiable.

Although the portable terminal 1000 is shown and described as including the coil module 100, the portable terminal 1000 may alternatively include any one of the coil modules 200, 700, and 800.

As set forth above, according to the embodiments disclosed herein, the manufacturing cost of the coil module may be reduced and the manufacturing yield thereof may be improved.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A coil module for wireless communications comprising:
a coil part formed by a molded substrate and comprising a solenoid shape; and
a magnetic member disposed in an insertion hole of the coil part.

2. The coil module for wireless communications of claim 1, wherein the substrate comprises a flexible circuit board.

3. The coil module for wireless communications of claim 1, wherein the substrate is a single-sided substrate comprising a base layer and a metal layer formed on one surface of the base layer.

4. The coil module for wireless communications of claim 3, wherein the metal layer and the base layer are disposed above and below the magnetic member, and an order in which the metal layer and the base layer are disposed above the magnetic member is the same as an order in which the metal layer and the base layer are disposed below the magnetic member.

5. The coil module for wireless communications of claim 3, wherein the metal layer comprises a first pattern connected to a connection terminal, a second pattern connected to the first pattern and comprising the solenoid shape, and a third pattern connected to the second pattern and connected to another connection terminal.

6. The coil module for wireless communications of claim 5, wherein
the first pattern comprises a bar shape extending in a length direction of the second pattern at an outer side of the second pattern, and
the third pattern comprises the bar shape extending in a width direction of the second pattern at an outer end portion of the second pattern.

7. The coil module for wireless communications of claim 5, wherein the second pattern comprises first pattern members disposed on the magnetic member, second pattern members disposed below the magnetic member, and connection pattern members disposed at opposite sides of the magnetic member and connecting corresponding ones of the first pattern members and the second pattern members to each other.

8. The coil module for wireless communications of claim 7, wherein short preventing grooves for preventing a short circuit with an adjacent connection pattern member, among the connection pattern members, are disposed at opposite sides of the connection pattern members.

9. The coil module for wireless communications of claim 7, wherein inclined parts are disposed at opposite end portions of the first pattern members and the second pattern members to form the insertion hole.

10. The coil module for wireless communications of claim 9, wherein the first pattern members are disposed above the connection pattern members and the second pattern members are disposed below the connection pattern members.

11. The coil module for wireless communications of claim 1, wherein the magnetic member comprises a magnetic sheet comprising a plate shape, and a cover sheet attached to opposite surfaces of the magnetic sheet.

12. The coil module for wireless communications for claim 1, wherein the magnetic member comprises a cross section having a concave-convex shape.

13. The coil module for wireless communications for claim 12, wherein the magnetic member comprises mounting grooves formed in opposite surfaces of the magnetic member, and wherein a pattern included in the coil part is inserted into the mounting grooves.

14. The coil module for wireless communications of claim 1, further comprising an exterior cover sheet attached to an outer surface of the coil part and enclosing the coil part.

15. A coil module for wireless communications comprising:
a coil part comprising a solenoid shape and formed by a molded metal plate; and
a magnetic member inserted into an insertion hole of the coil part,wherein the magnetic member comprises a magnetic sheet comprising a plate shape and a cover sheet attached to opposite surfaces of the magnetic sheet.

16. The coil module for wireless communications for claim 15, wherein the magnetic member further comprises a cross section having a concave-convex shape.

17. The coil module for wireless communications for claim 16, wherein the magnetic member further comprises mounting grooves formed in opposite surfaces of the magnetic sheet, wherein a pattern included in the coil part is inserted into the mounting grooves.

18. A method to manufacture a coil module for wireless communications, the method comprising:
etching a metal layer on a flexible circuit board comprising the metal layer and a base layer;
shaping the flexible circuit board to comprise a solenoid shape disposed around an insertion hole; and
inserting a magnetic member in the insertion hole.

19. The method of claim 18, wherein the shaping of the flexible circuit board to comprise the solenoid shape comprises molding the flexible circuit board to comprise a first pattern configured to be connected to a connection terminal, a second pattern connected to the first pattern and comprising the solenoid shape, and a third pattern connected to the second pattern and configured to be connected to another connection terminal.

20. The method of claim 19, wherein the shaping of the flexible circuit board further comprises pressurizing the second pattern to form the insertion hole.

21. The method of claim 18, wherein the shaping of the flexible circuit board further comprises molding the flexible circuit board by a press-blanking process.
